(19) United States
(12) Patent Application Publication
(10) Pub. No.: US 2010/0232214 A1
(43) Pub. Date: Sep. 16, 2010

(54) STATIC MEMORY MEMORY POINT AND APPLICATION TO AN IMAGE SENSOR

(75) Inventor: Caroline Papaix, Quaix En Chartreuse (FR)

Correspondence Address: LOWE HAUPTMAN HAM & BERNER, LLP, 1700 DIAGONAL ROAD, SUITE 300, ALEXANDRIA, VA, 22314, US

(73) Assignee: E2V SEMICONDUCTORS, Saint Egreve (FR)

(21) Appl. No.: 12/678,116

(22) PCT Filed: Sep. 12, 2008
(86) PCT No.: PCT/EP2008/062114

§ 371 Date: Mar. 12, 2010

(30) Foreign Application Priority Data
Sep. 14, 2007 (FR) 07/06463

(51) Int. Cl. G11C 11/00; H04N 5/335

(52) U.S. Cl. 365/154; 348/308; 348/E05.091

(57) ABSTRACT

The invention relates to a memory point of SRAM (static memory) type memory. The memory point conventionally comprises two inverters mounted head-to-tail between two nodes, and at least one access transistor able to be made conductive during a writing phase and linked between a first node and a line of data to be written, characterized in that it comprises an isolating transistor inserted in series between the output of a first inverter and the first node, the isolating transistor being controlled by an insulation signal at the start of a writing phase. The current consumption is reduced when the state of the memory point has to be inverted.

### RELATED APPLICATIONS

The present application is based on International Application Number PCT/EP2008/062114, filed Sep. 12, 2008, and claims priority from French Application Number 0706463, filed Sep. 14, 2007, the disclosures of which are hereby incorporated by reference herein in their entirety.

### FIELD OF THE INVENTION

The invention relates to the matrix image sensors produced in CMOS technology.

### BACKGROUND OF THE INVENTION

They comprise a matrix of photosensitive pixels arranged in lines and columns. Each pixel comprises an active circuit with a photodiode and a few transistors. The charges photogenerated in the pixels are read line by line: a line conductor common to all the pixels of a line selects all the pixels of that line and authorizes the transmission to a column conductor of an electrical signal representing the charges photogenerated in the pixel. The column conductor is common to all the pixels of a column of the matrix but, since the addressing is done line by line, just one pixel of the column is actually linked to the column conductor at a given instant of the read process.

The signal transmitted to the column conductor is an analogue voltage or current, the amplitude of which is representative of the charges photogenerated in a pixel. The reading is generally done in two stages: the charges present in the pixel are read after a charge integration period, then the pixel is reinitialized (pending a new integration) and the reinitialized pixel is immediately read again before the new integration begins; the analogue signal representative of the lighting of the pixel is the difference between the signals resulting from these two immediately consecutive readings.

The analogue signal representing this difference is converted into a digital signal on M bits (for example M=10 bits) by an analogue-digital converter. The reading of a line of the matrix therefore gives rise to P words of M bits if there are P columns in the matrix. There can be an analogue-digital converter at the foot of each column, which makes it possible to obtain these P words of M bits very rapidly.

The digital information corresponding to the P words must be read rapidly before the reading of the new image line of the matrix modifies them. It is therefore necessary to read the P words very rapidly before P new words arrive. Typically, all the words of a line must be read within approximately 50 microseconds.

In a particular architecture, the P words of M bits are stored in an addressable RAM memory, so that it is then possible to read at will and asynchronously the content of this memory without being obliged to sequentially and synchronously read all the words of the memory. This can be important in the case where the number of columns is high (example: P=1048 columns) and where there is not necessarily a need for all the stored information. The selective addressing of the words makes it possible to speed up the reading in certain cases.

To further accelerate the line-by-line reading of the information obtained from the matrix, it is possible to use two memories of P words of M bits operating alternately: one receives the digitized information obtained from the columns of pixels while the content of the other is read, and on the next line, the roles of the two memories are reversed.

FIG. 1 diagrammatically represents this architecture, with a matrix MT of sensors, a decoder DEL for addressing the matrix line by line for reading, a bank AD of read differential amplifiers at the foot of the columns of the matrix, a bank CAN of analogue-digital converters (in this case, as many converters as there are columns), and finally two RAM memories designated RAM1 and RAM2, addressable by a column decoder DEC to designate a particular word of the RAM (therefore a particular column of the matrix of pixels). The two memories operate alternately under the control of the line decoder, the alternation taking place between one line and the next during reading.

The RAM memories can be made up of conventional SRAM (static RAM) type memory points, the dynamic RAM memories having the drawback of retaining the information less well because the information is stored in capacitors which have leakage currents that tend to degrade the content of the information.

The SRAM-type conventional memory point, able to store a bit of information, is represented in FIG. 2. It is located between two complementary lines of data DL and DLB (one transporting the bit to be stored, the other transporting the binary complement of this bit). These lines are used for writing and reading and therefore constitute both inputs obtained from an analogue-digital converter and outputs intended to transport to a load circuit the information read from the memory.

The memory point of FIG. 2 comprises a line WL controlling the reading or writing of the point; if this line receives a high potential level, it authorizes the selection of this memory point and this point can be written or read. In write mode, the data to be written and its complement are established on the bit lines DL and DLB and force the memory point into one of two possible states. In read mode, the current state of the memory point forces one level or another on the bit line DL and a complementary level on the line DLB.

The memory point essentially comprises, in its simplest configuration, two nodes representing the complementary states stored in the memory point, two inverters mounted head-to-tail between these two nodes, and two access transistors for linking one of the nodes to the line DL and the other to the complementary line DLB; these transistors are controlled by the read or write control line WL. There are six transistors in all, each inverter possibly comprising two transistors mounted in push-pull configuration.

The writing of this memory point consumes more current when the state of the point has to be changed than when the preceding state of the point simply has to be retained. In practice, at the moment when a change of state is written, the line DL must force its logical state on one of the memory nodes while one of the inverters tends to force precisely the contrary state (the former state) on this same node. This conflict generates a current consumption until the line has taken over.

Now, circumstances can occur in which it is precisely necessary to invert the state of a large number of memory points out of the P×M points, which generates a very high instantaneous consumption.

This peak consumption phenomenon is mitigated in certain embodiments by the construction of the analogue-digital converters which can be so-called “ramp” converters which operate on the following principle: a counter of M bits counts clock pulses from the start of a very linear voltage ramp and a comparator associated with each column compares the level of the ramp to the level of the analogue signal to be converted; when the level of the ramp reaches the level of the signal to be converted, the comparator switches over and triggers the entry in the memory of a word of M bits made up of the current content of the counter, this word therefore depending directly on the level of the signal to be converted. The entries in the memory are made under the control of the comparator associated with each column of pixels, and consequently they can be staged in time according to the signal levels of the different pixels.

However, here too, there are circumstances in which all the pixels were at one and the same level defined by a word, and must all change to one and the same level defined by another word whose bits all precisely complement the bits of the preceding word. Such is the case when changing from a black line (unlit pixels) to a white line (pixels all lit with one and the same level), or vice versa. Although this very high writing current peak problem is less frequent when the converter is a ramp converter, the case is possible and the circuits must therefore be dimensioned to take it into account even though it is rare.

It is proposed here to modify the structure of the memory point of the RAM memory in which the digitized content of the lines of pixels successively addressed is temporarily stored, in order to reduce the current consumption peaks when writing.

### SUMMARY OF THE INVENTION

According to the invention, the storage memory point for an individual bit further comprises two inverters mounted head-to-tail between two nodes, but the connection between the output of one of them and a node can be interrupted by a series transistor which is temporarily blocked at the start of each write pulse.

The conflict induced by the head-to-tail inverters is thus eliminated at the start of the write. It is simplest moreover to block this transistor throughout the duration of a write pulse and therefore control the transistor by the write pulse itself, a pulse which, in the case of FIG. 2, serves to render conductive the access transistors placed between the nodes and the lines of data.

Consequently, according to the invention, the memory point is characterized in that it comprises two inverters mounted head-to-tail between two nodes and having their inputs connected to these nodes, an isolating transistor being inserted in series between the output of a first inverter and a first node, an access transistor able to be made conductive during a writing phase being linked between this node and a data write line, the isolating transistor being controlled by an isolation signal at the start of a writing phase.

In practice, it is simpler to provide for the isolating transistor to be blocked throughout the duration of the writing phase, although this is not necessary. Provision is therefore preferably made for the access transistor and the isolating transistor to be controlled in phase opposition by one and the same write signal which renders the access transistor conductive while it blocks the isolating transistor and vice versa.

The memory point can be constructed symmetrically between two complementary data write lines, as in FIG. 2, with an access transistor between each line of data and a respective node; in this case, a respective isolating transistor is needed between the output of each inverter and a corresponding node. The two data write lines are then used both to transport a datum to be written in the memory point and to extract a data read from the memory point.

However, in another configuration, a dissymmetrical memory point is proposed that has a line of data used for writing and another line of data used for reading. The isolating transistor is unique. The access transistor is controlled by a write signal. A read transistor is provided in the memory point, and another access transistor is provided, controlled by a read signal, to link the read transistor to the read data line; the conduction of the read transistor is controlled by the binary state of the second node. In this configuration, the reading is done by observing the current consumption drawn from the read line by the read transistor: stronger if the transistor is made conductive by a binary state of the second memory node, less strong if it is blocked by the complementary binary state of this node.

In these different configurations, it is possible to provide for a small additional inverter to be inserted between the data write line and the corresponding access transistor, to reduce the overall capacitive charge linked to the line.

The RAM memory point according to the invention is particularly suited to use in the context indicated above, namely, in a CMOS image sensor comprising a matrix of photosensitive pixels arranged in N lines and P columns, an analogue-digital converter linked to a column conductor and able to supply a word of M bits representing the signal obtained from a pixel of the column, and a RAM memory (or preferably two memories operating alternately, one in write mode and the other in read mode) able to receive and store P words obtained from the analogue-digital conversion and corresponding to P pixels of a line, and able to then restore these P words on a read command.

Still other objects and advantages of the present invention will become readily apparent to those skilled in the art from the following detailed description, wherein the preferred embodiments of the invention are shown and described, simply by way of illustration of the best mode contemplated of carrying out the invention. As will be realized, the invention is capable of other and different embodiments, and its several details are capable of modifications in various obvious aspects, all without departing from the invention. Accordingly, the drawings and description thereof are to be regarded as illustrative in nature, and not as restrictive.

### BRIEF DESCRIPTION OF THE DRAWINGS

The present invention is illustrated by way of example, and not by limitation, in the figures of the accompanying drawings, wherein elements having the same reference numeral designations represent like elements throughout and wherein:

FIG. 1, already described, represents the general architecture of a matrix CMOS image sensor;

FIG. 2 represents the structure of a memory point of the memory storing the digital words representing the pixels of a line of the sensor;

FIG. 3 represents an exemplary embodiment of a memory point according to the invention;

FIG. 4 represents a different embodiment, dissymmetrical, of the memory point;

FIG. 5 represents an embodiment variant of FIG. 4;

FIG. 6 represents a read circuit in the case of two memories operating alternately.

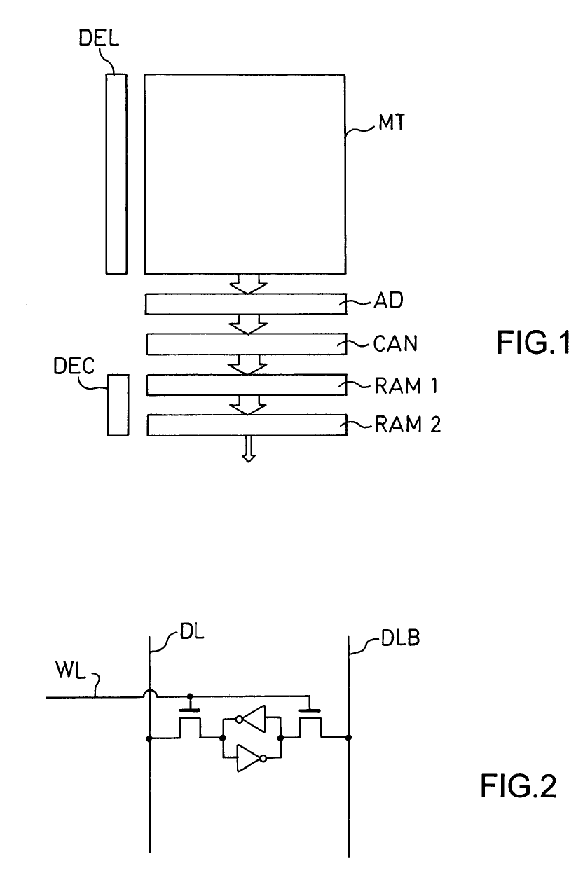

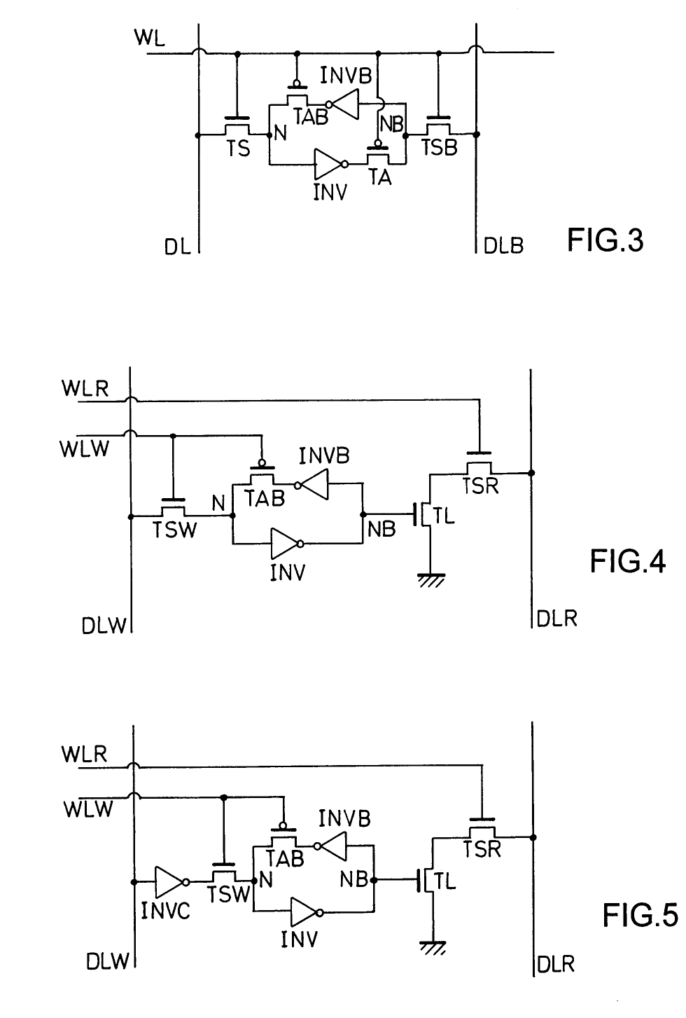

FIG. 3 represents a diagram of the memory point according to the invention, in a symmetrical construction. The point is one of the memory points of the memory located downline from a bank of analogue-digital converters; this memory can comprise two memories RAM1 and RAM2 as explained in relation to FIG. 1.

There is a line of data DL and a complementary line of data DLB, both used for writing a bit in the memory point and reading a bit stored in the memory point. For writing, complementary logic levels must be applied to these two lines. For reading, the lines supply two complementary logic levels.

The memory point comprises two nodes N and NB which are in complementary binary states, the state of the node N being, for example, that which defines the state of the memory point. Writing involves imposing on the node N the state of the line DL and on the node NB the state of the line DLB. Reading involves transferring to the line DL information relating to the state of the node N and transferring to the line DLB complementary information relating to the state of the node NB.

Two transistors controlling access to the memory point, TS and TSB, are inserted respectively between the node N and the line DL (transistor TS) and between the node NB and the line DLB (transistor TSB). These transistors are made conductive by a read or write control line WL common to all the memory points of the memory (there is a specific line WL for each of the two memories if there are two memories RAM1 and RAM2 as in FIG. 1). Outside of the memory read or write moments, the access control transistors remain blocked.

For writing, two complementary voltages (high level and low level) are applied to the lines DL and DLB and the access control transistors TS and TSB transfer these voltages to the nodes N and NB respectively.

For reading, the lines are preferably precharged to an intermediate potential between a high level and a low level; one of the nodes N and NB tends to increase the potential of the line to which it is connected; the other tends to reduce the potential. The modification of the potential of the lines DL and DLB is detected to determine the state of the memory point.

A first inverter INV has an input linked to the node N and an output linked to the node NB via an isolating transistor TA. A second inverter INVB has an input linked to the node NB and an output linked to the node N via an isolating transistor TAB.

These isolating transistors TA and TAB are made conductive and blocked in phase opposition with the access control transistors TS and TSB. For example, the transistors TS and TSB are NMOS transistors and the isolating transistors TA and TAB are PMOS transistors, which makes it possible to make a command in phase opposition by using the same read or write control line WL to control the four transistors.

To write information into this memory point, the voltage levels present on the lines DL and DLB are applied to the nodes N and NB respectively by making the transistors TS and TSB conduct; the nodes N and NB are then insulated from the outputs of the inverters INV and INVB by the transistors TA and TAB; the inverters can therefore not oppose a change of level of the nodes N and NB in the case where the new information to be stored in memory is the binary complement of the information currently entered.

Immediately the write command is interrupted on the line WL, the isolating transistors TA and TB once again become conductive and the inverters INV and INVB stably confirm the states of the nodes N and NB, since the inverter INV can now apply to the node NB the complement of the state of the node N and the inverter INVB can apply to the node N the complement of the state of the node NB.

For reading, a command is once again applied to the line WL to make the access control transistors TS and TSB conduct. The isolating transistors TA and TAB are blocked and the nodes N and NB are in communication only with the lines DL and DLB respectively. The information is then stored in capacitive form in these nodes. If the lines DL and DLB have been precharged to an intermediate voltage between the high and low logic levels that can be stored in the nodes N and NB, making the nodes N and NB communicate with the lines DL and DLB will drain a current in one direction or the other depending on the state of the node concerned. Reading will be done at the foot of the column by observing the direction of the difference of the currents circulating in the lines DL and DLB at the time of the read command by the line WL.

It may, however, be desirable to avoid doing a reading with a phase for precharging the data lines. In practice, these data lines are strongly capacitive since very many memory points can be connected to them, for example 1048 memory points on each data line. The precharging therefore consumes a high current. Also, reading with a precharging phase is a synchronous-type reading, that is, with a precise timing between two read phases, whereas an asynchronous-type reading may be desired, simply involving sending a read command and immediately collecting the data contained at the designated memory point address.

For this, an embodiment variant of the memory point is proposed, in which the read command is distinct from the write command. The result is a dissymmetrical memory point scheme, as represented in FIG. 4.

In the scheme of FIG. 4, a data line DLW is provided to add the information to be written and another data line DLR is provided to export the information read. There are therefore not two complementary data lines transporting the information and the complement of the information to be read or to be written.

Also, there is a write control line WLW and a read control line WLR distinct from the line WLW. These two lines are common to all the points of the memory (of just one of the two memories if there are two memories RAM1 and RAM2 operating alternately).

The memory point also comprises two nodes N and NB having complementary binary states.

The node NB is directly linked to the output of an inverter INV, the input of which consists of the node N and it therefore systematically takes the complementary binary state of that of the node N. It is the node NB that will be used, as will be seen, to read the information contained in the memory point.

The node N is linked to the output of an inverter INVB, via an isolating transistor TAB which serves the same purpose as the transistor TAB in FIG. 3 and which is blocked during the write command.

Two transistors controlling access to the memory point are provided: the transistor TSW which is controlled by the write control line WLW to be conductive during the write, and the transistor TSR which is controlled by the read control line WLR to be conductive during the reading. The transistor TSW is linked between the write data line DLW and the node N. The transistor TSR is linked between the read data line DLR and a current measurement transistor TL linked elsewhere to a fixed potential. The gate of the transistor TL is linked to the node B so that this transistor is blocked or made conductive depending on the state of the node NB. If it is blocked, it draws no current from the line DLR. If it is conductive, it can draw a current from the line DLR when the read mode access transistor TSR is made conductive as well. It is therefore possible to determine at the foot of line DLR the state of the memory point on the application of a read command to the line WLR.

As in FIG. 3, if the transistor TSW is an NMOS transistor, and if the transistor TAB is a PMOS transistor, they can both be directly controlled by the write control line WLW for one to be blocked while the other is conductive and vice versa.

Preferably, an inverter INVC (or a buffer amplifier) is inserted between the write data line DLW and the access transistor TSW, to reinforce the data to be written, to avoid the information added by the line being attenuated by its passage through the transistor TSW. This configuration is represented in FIG. 5. The inverter could also be placed between the transistor TSW and the node N rather than between the line DLW and the transistor TSW.

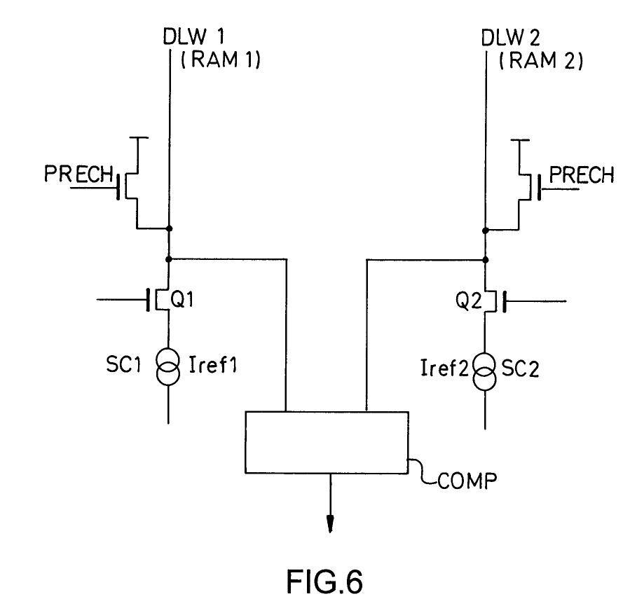

One simple way of reading the state of the memory point is represented in FIG. 6, in the case of a memory divided into two memories RAM1 and RAM2 operating alternately.

The read data line DLW1 of the first memory RAM1 and the read data line DLW2 of the second memory RAM2 are supplied alternately by reference currents Iref1 and Iref2 that are identical and supplied by current sources SC1 and SC2. A respective control transistor Q1 authorizes the passage of the current in the line DLW1 only while the line DLW2 is being read and, conversely, a transistor Q2 authorizes the passage of the current in the line DLW2 only while the line DLW1 is being read.

The ends of the lines DLW1 and DLW2 are linked to a current comparator COMP.

Before a read step, the two lines are precharged to a sufficient voltage (in practice, a voltage greater than the threshold voltage of the circuit's NMOS transistors).

To read the line DLW1, the transistor Q1 is made conductive and the line DLW2 is passed through by a reference current Iref2.

The current comparator receives on one side a current which is the difference between the precharging current of the line DLW2 and the reference current Iref2 and, on the other side, the precharging current of the line DLW1. The precharging currents are identical, the lines having the same construction and the same relatively high total capacitance. The difference of the currents is therefore Iref2 in a first read step.

Then, at the moment when a read command is applied to the line WLR of the memory point of the first memory, the current drawn by the read transistor TL (FIG. 4 or FIG. 5) modifies the imbalance of the currents in the comparator. The current difference becomes greater or less than Iref2 depending on the state read in the memory point.

This variation is detected and makes it possible to collect the information on the state of the memory point. To read the other memory, the role of the two lines is reversed.

The advantage of this arrangement is that the reading is not disturbed or slowed down by the spurious capacitances of the data lines, one of the data lines (the one not being read) being used to compensate the effect of the spurious capacitances of the other (the one being read).

It will be readily seen by one of ordinary skill in the art that the present invention fulfils all of the objects set forth above. After reading the foregoing specification, one of ordinary skill in the art will be able to affect various changes, substitutions of equivalents and various aspects of the invention as broadly disclosed herein. It is therefore intended that the protection granted hereon be limited only by definition contained in the appended claims and equivalents thereof.

1. Memory point of a static memory SRAM, comprising two inverters mounted head-to-tail between two nodes and having their inputs connected to theses nodes, and at least one access transistor able to be made conductive during a writing phase and linked between a first node and a line of data to be written, said memory point comprising an isolating transistor inserted in series between the output of a first inverter and the first node, the isolating transistor (TAB) being controlled by an isolation signal at the start of a writing phase.

2. Memory point according to claim 1, wherein the access transistor and the isolating transistor are controlled in phase opposition by one and the same write control line which makes the access transistor conductive while it blocks the isolating transistor and vice versa.

3. Memory point according to claim 1, comprising a second line of data to be written conveying binary information complementing that of the first line of data, with an access transistor between each line of data and a respective node, a respective isolating transistor being provided between the output of each inverter and a corresponding node.

4. Memory point according to claim 1, comprising a line of data to be read distinct from the line of data to be written, a read transistor being provided in the memory point, controlled by the second node, and an access transistor being provided, controlled by a read control line, to link the read transistor to the line of data to be read.

5. Memory point according to claim 4, wherein an additional inverter is inserted between the data write line and the corresponding access transistor.

6. CMOS image sensor comprising a matrix of photosensitive pixels arranged in N lines and P columns, an analogue-digital converter linked to a column conductor and able to supply a word of M bits representing the signal obtained from a pixel of the column, and at least one memory M*P memory points, able to receive and store P words obtained from the analogue-digital conversion and corresponding to P pixels of a line, and to then restore these P words on a read command, characterized in that each memory point is constructed according to claim 1.

7. Image sensor according to claim 6, comprising two memories of M*P memory points operating alternately, one in write mode and the other in read mode.

8. Memory point according to claim 2, comprising a line of data to be read distinct from the line of data to be written, a read transistor being provided in the memory point, controlled by the second node, and an access transistor being provided, controlled by a read control line, to link the read transistor to the line of data to be read.

9. Memory point according to claim 8, wherein an additional inverter is inserted between the data write line and the corresponding access transistor.
